(19) United States
(12) Patent Application Publication
(10) Pub. No.: US 2013/0204564 A1
(43) Pub. Date: Aug. 8, 2013

(54) SYSTEM AND METHOD FOR INTERPRETING A SIGNAL FROM A TRANSDUCER

(71) Applicant: Douglas C. Moore, Chicago, IL (US)

(72) Inventor: Douglas C. Moore, Chicago, IL (US)

(73) Assignee: D & R TECHNOLOGY, LLC, Carol Stream, IL (US)

(21) Appl. No.: 13/696,968

(22) PCT Filed: May 10, 2011
(86) PCT No.: PCT/US11/35840

§ 371 Date: Feb. 4, 2013

Related U.S. Application Data
(60) Provisional application No. 61/332,979, filed on May 10, 2010.

(51) Int. Cl. G01D 18/00; G06F 15/00; G01R 35/00

(52) U.S. Cl. CPC G01D 18/00; G01R 35/00; G06F 15/00
USPC 702/86

(57) ABSTRACT

The sensor system includes a transducer having an output and a microcontroller in communication with the output of the transducer. Generally, the transducer is a Hall effect device which is capable of measuring a magnetic field. The transducer outputs a transducer signal to the microcontroller. The transducer signal has a generally non-linear range. The microcontroller receives the non-linear transducer signal and is configured to output a signal based on the transducer signal that has been modified to have a linear range, as opposed to the non-linear range of the transducer signal.

### BACKGROUND

1. Field of the Invention

The invention generally relates to sensor systems having transducers.

2. Description of Related Art

Transducers, such as Hall effect devices (HEDs), have a voltage output that varies in response to changes in a detected magnetic field. In its simplest form, the Hall effect device (HED) operates as an analog transducer, directly returning a voltage. Electrical current carried through a conductor will produce a magnetic field that varies with that current, and the Hall effect device can be used to measure the current without interrupting the circuit by sensing the magnetic field around the conductor. Typically, this type of sensor is integrated with a magnetically permeable core that surrounds the conductor carrying the current to be measured.

However, the composition of the magnetic core is important and will have a significant impact on the voltage output of the Hall effect device. More specifically, it is desirable to have a voltage output from the sensor that is linear with respect to the strength of the magnetic field emanating from the main conductor which is proportional to the current being sensed. In order to accomplish this, prior art solutions would generally utilize cores that were made of silicon-iron, and other permeable materials. However, in order to manufacture a core that would yield a linear output signal, a significant amount of material would be required to produce a very linear response. This generally leads to a fairly large and bulky sensor device. Advancements in materials lead to the use of nickel-iron cores, which produce better accuracy because of lower remenance and hysteresis in the output response. Never the less, these other materials still require significant volume to yield a linear signal. Moreover, using alternate materials having better performance can lead to a core that is relatively expensive to manufacture. Therefore, manufacturers are left with multiple limitations: manufacturing lower priced, lower performance devices, or higher performance higher priced devices with both being bulky.

### SUMMARY

The sensor system of this invention includes a transducer having an output and a microcontroller in combination with the output of the transducer. Generally, the transducer is a Hall effect device which is capable of measuring a magnetic field. The transducer outputs an electrical signal to the microcontroller. The transducer signal generally has a linear relationship to the magnetic field passing through it, but a non-linear relationship to the actual current the sensor is intended to sense. The microcontroller receives the non-linear transducer signal and compensates accordingly to produce a linear sensor output signal. As there is no need for the transducer to have a linear output (with respect to the actual current being sensed), the core size can be made much smaller. This results because the magnetic field in the core can be allowed to reach near saturation levels with the resulting nonlinearities being compensated by the microcontroller. Prior art relies on large core masses to achieve output linearity. With the microcontroller correcting core nonlinearities, a much less expensive core can be used. These less expensive cores can be both smaller and made of lower cost materials.

Further objects, features and advantages of this invention will become readily apparent to persons skilled in the art after a review of the following description, with reference to the drawings and claims that are appended to and form a part of this specification.

### BRIEF DESCRIPTION OF THE DRAWINGS

FIG. 1 illustrates a sensor system having a transducer and a microcontroller;

FIG. 2 illustrates another embodiment of the sensor system having two transducers and a microcontroller; and

FIG. 3 illustrates a method for interpreting the signal from the transducers of FIG. 1 or 2.

### DETAILED DESCRIPTION

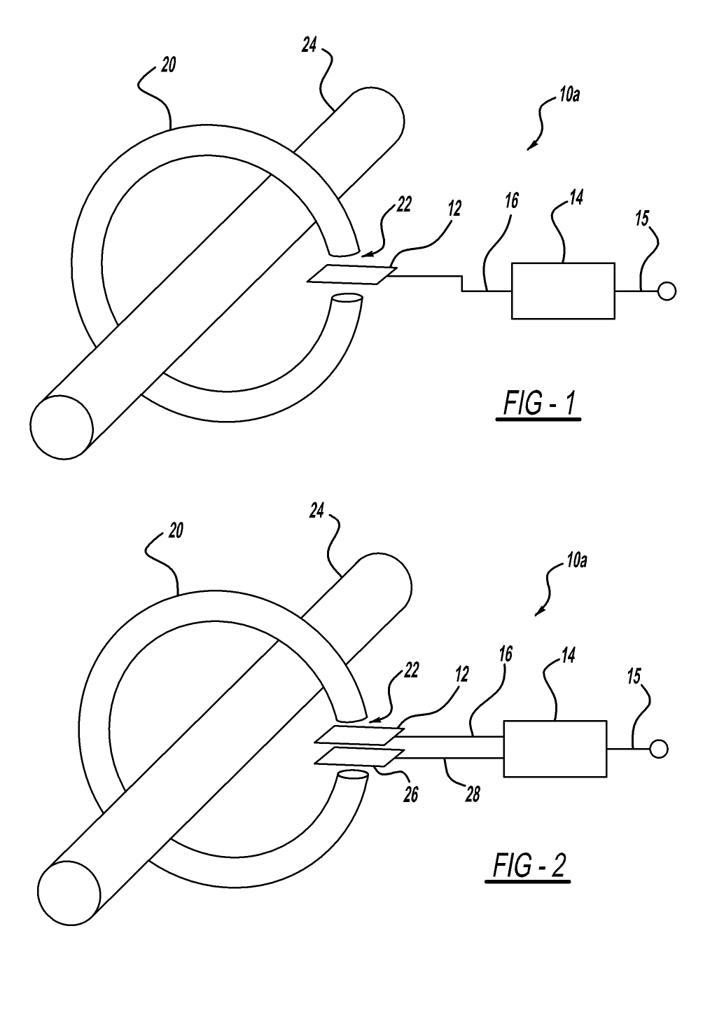

Referring to FIG. 1, a sensor system 10a is shown. The sensor system 10a includes as its primary components a transducer 12 and a microcontroller 14. The transducer 12 has an output 16 in communication with the microcontroller 14. As will be explained in the paragraphs that follow, the transducer 12 is configured to output a signal to the output 16 that is based on a parameter measured by the transducer 12. In general, the signal output by the transducer 12 to the output 16 has a non-linear relationship to the sensed physical quantity—the current in the main conductor is the physical quantity being sensed by a current sensor.

The transducer 12 is designed to measure the physical quantity being sensed. In the case of a current sensor, the current in the main conductor is sensed indirectly by sensing the magnetic flux in the surrounding core. This flux is proportional to the magnetic field passing though the transducer 12. One type of transducer used for this purpose is a Hall effect device (HED). When the transducer 12 is a Hall effect device, the transducer 12 can be constructed from Silicon, Germanium Arsenide, or Indium Arsenide semiconductor. When the transducer 12 is held such that a magnetic field lines are passing at right angles through the transducer 12, an output signal is generated and sent to the output 16, which is then sent to the microcontroller 14. As was explained previously, this output signal generally has a non-linear relationship to the physical quantity being sensed. In other words, it may be linear, but is not required to be such, and may be deliberately designed to be nonlinear.

The sensor system 10a may also include a C-shaped magnetic core 20 having a relatively small gap 22 formed therein. The transducer 12 is located within the gap 22. A conductor 24 is located adjacent to the core 20 and generally passes though the middle of the C-shaped core 20. Although the conductor 24 is shown as having a single pass through the core 20, the conductor 24 could be configured to have multiple turns of the core 20. The core 20 is preferably manufactured from a high permeability magnet material, such as iron or ferrite. Some common materials utilized to make the core 20 include both silicon-iron and nickel-iron. Core cross-sectional area is chosen to produce a reasonable nonlinear response between core flux and current in the main conductor.

For a given full-scale sensing range, the cross-sectional area is chosen to allow some core saturation but not total saturation at full scale current. With a reduced-size core of Nickel/Iron, the curved non-linear response 42 is shown in FIG. 4. This is the raw HED signal adjusted for its implied current value. The X axis of FIG. 4 is actual applied current in the main conductor. The Y axis is apparent current given the HED output signal. The straight line 44 is the ultimate output of the corrected signal from the microcontroller, whereas, the curved line 42 is a scaled and offset version of the HED output. In other words, if the raw nonlinear HED output were simply offset by 2.5V and scaled to have the appropriate full scale value at full scale applied current, this graph of FIG. 4 would result. This way one can see the degree to which the linearization process is altering the output signal.

The slope of this response is double that of a sensor with a full size core installed at or near zero current. The reason for this is that the air gap 22 of the core 20 is smaller than for a full size core, but the cross-sectional area smaller as well. So the flux in the reduced-size core builds up much faster than in a full-size core as the sensed current increases from zero. This means that the digital resolution is much finer because the analog to digital counts increment faster with each added ampere of sensed current. So, in section 48, there is a quasi linear output, but in sections 50 and 52, the output is non-linear.

At near full scale we have the opposite effect of more quantization error since the slope is about 0.33 near location 46 and at sections 50 and 52. However, there is a diminished need for high accuracy at high current levels, so the tradeoff is a net benefit. This produces a data compression advantage of 6:1 from zero to full scale. The linearized response 44 is created by a lookup table in the microcontroller 14 that corrects for the pronounced curvature in the raw signal 42 at sections 50 and 52. There is an added benefit that can be realized if the nonlinear shape 42 of the sensor's transfer function is maintained all the way to the control module (receiving the sensor's signal); noise and error that enter the signal path from sensor to module are reduced. If the sensor fully linearizes itself, this benefit cannot be realized.

To accomplish this added benefit, the microcontroller 14 would be programmed to fit its transfer function to a predetermined shape. The receiving control module would then have its own lookup table to correct from this predetermined shape to a fully linear response 44.

As stated previously, the transducer 12 is located within the gap 22 so as to be perpendicular to the magnetic field in the core. As the current varies in the main conductor 24, the magnetic field generated will vary as well. This magnetic field generated within the core 20 is then measured by the transducer 12 and outputted to the output 16, which is connected to the microcontroller 14. The microcontroller 14 is then configured to output a linear signal to the output 15 of the microcontroller 14. Generally, the non-linear signal from the transducer 12 is converted to a linear signal by the microcontroller 14. However, the microcontroller can be configured to output a predetermined nonlinear response to the physical quantity being sensed.

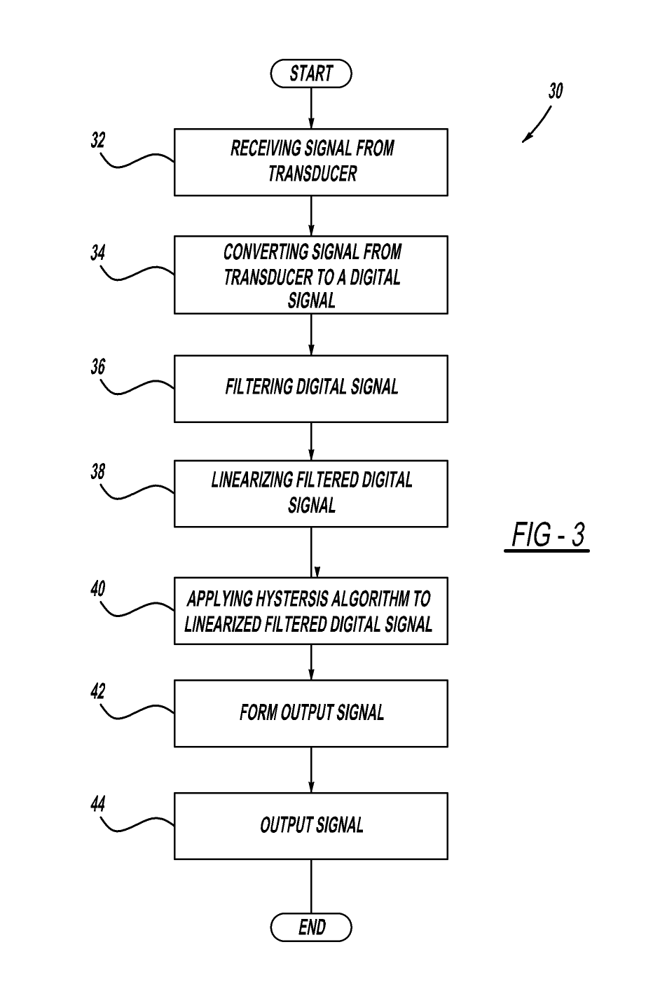

Referring to FIG. 2, another embodiment of the sensor system 10b is shown. The sensor system 10b of FIG. 2 is similar to sensor system 10a of FIG. 1 and therefore like reference numerals are used to define like elements. The sensor system 10b of FIG. 2 differs from that of the sensor system 10a of FIG. 1 in that the sensor system 10b includes a second transducer 26 having an output 28 connected to the microcontroller 14. Like transducer 12, transducer 26 is also located in the gap 22 defined by the core 20. Utilizing two transducers 12 and 26 adds additional resolution to the system especially at the low end range of the system 10b. As stated before, the signals outputted by the transducers 12 and 26 are generally non-linear, however, one transducer has a significantly higher sensitivity as the other. Therefore, the microcontroller algorithms can make use of the high-sensitivity input to increase the system resolution at the low end of the sensing range. The high end of the range is sensed using the lower sensitivity transducer. This gives the sensor the ability to operate like two sensors in one. Yielding high accuracy and resolution at the low end while preserving the large dynamic range needed to sense full-scale currents. Prior art achieved this in a much less integrated fashion by simply combining two complete sensors in the same package whereas here, only an additional transducer element has been added which results in a much more efficient and compact design.

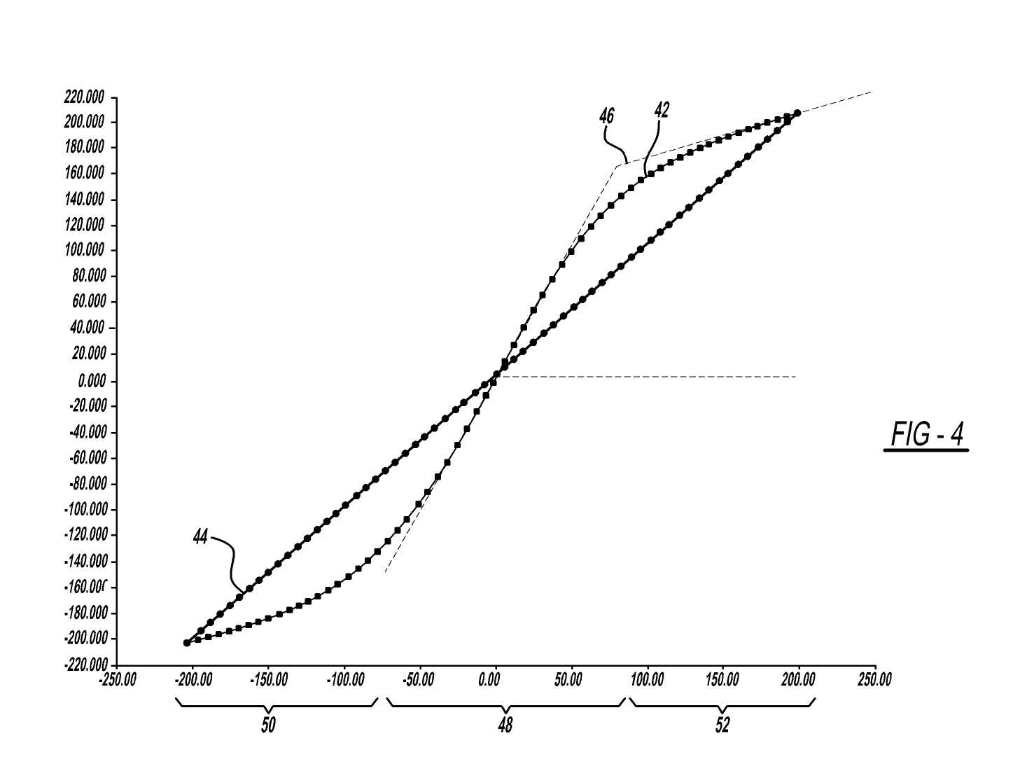

Referring to FIG. 3, a method 30 for interpreting the signals from the transducers 12 and 26 is shown, when describing the method 30 of FIG. 3, reference will be made to FIGS. 1 and 2. The method 30 begins with step 32, wherein the microcontroller 14 receives a signal from the transducer 12. The microcontroller 14 may also receive a signal from the transducer 26 as well. Next, in step 32, the microcontroller 14 converts the signals from the transducers 12 and 26 to digital signals by use of analog to digital converters in the microcontroller. Generally, this digital signal is a 12-bit value, but may be any size of value suitable for representing information received from the transducers 12 and/or 26.

Thereafter, in step 34, the digital signals are then filtered using low-pass and median-value filter algorithms. Generally, the filter utilized may be either a median value filter and/or an infinite impulse response low pass filter. A median value filter essentially replaces each entry with the median of neighboring entries. The pattern of neighbors is called the “window”, which slides, entry by entry, over the entire signal. For one-dimensional signals, the most obvious window is just the first few preceding and following entries, whereas for 2-D (or higher-dimensional) signals such as images, more complex window patterns are possible (such as “box” or “cross” patterns). An infinite impulse response low pass filter processes time-varying input signals to produce output signals, subject to the constraint of linearity.

In step 36, the filtered digital signal is then linearized using a lookup table. The lookup table contains a conversion value for converting the filtered digital signal to a linearized analog of the physical quantity being sensed. More specifically, each entry in this lookup table relates a physical quantity value with a filtered transducer value. The microcontroller 14 looks up each digitized transducer value in the table and then maps this to a corresponding linearized value. The lookup table is learned at the time of manufacture by experimentally applying test currents or stimuli to the sensor after assembly. The microcontroller 14 is in communication with the test equipment and provides the necessary data needed to assembly the lookup table. Once, the test equipment determines the proper values for the table for the sensor under test; these values are downloaded to the microcontroller 14. In normal sensor operation, the table can be read to perform needed linearization, but the values initially loaded to the table are never changed throughout the life of the sensor.

In step 38, the microcontroller may optionally apply hysteresis algorithm for Reminance Cancellation. Generally, the hysteresis algorithm utilizes the Jiles-Atherton model of the core. High range open loop current sensors often use core materials like silicon iron that can have significant reminance. This reminant effect adds error to the current sensor readings significantly reducing performance. The core behavior is predicted using a Jiles-Atherton type hysteresis model. (see references) This is a set of non-linear implicit ordinary differential equations which must be solved numerically.

The Jiles-Atherton hysteresis model (inverse) is as follows:

$$1. \frac{d M}{d B} = \frac{( 1 - c ) \frac{d {M}_{irr}}{d {B}_{e}} + \frac{c}{{μ}_{0}} \frac{d {M}_{an}}{d {H}_{e}}}{1 + {μ}_{0} ( 1 - c ) ( 1 - α ) \frac{d {M}_{irr}}{d {B}_{e}} + c ( 1 - α ) \frac{d {M}_{an}}{d {H}_{e}}}$$

$$2. {M}_{an} = {M}_{s} [ coth \frac{{H}_{e}}{a} - \frac{a}{{H}_{e}} ]$$

$$3. \frac{d {M}_{an}}{d {H}_{e}} = \frac{{M}_{s}}{a} [ 1 - {coth}^{2} \frac{{H}_{e}}{a} - {( \frac{a}{{H}_{e}} )}^{2} ]$$

$$4. {H}_{e} = H + α M$$

$$5. \frac{d {M}_{irr}}{d {B}_{e}} = \frac{{M}_{an} - {M}_{irr}}{{μ}_{0} k δ}$$

$$where$$

$$δ = sign ( \frac{d H}{d t} ) , \\ and$$

$$6. M = {M}_{irr} ( 1 - c ) + {cM}_{an}$$

$$7. {B}_{e} = {μ}_{0} {H}_{e}$$

$$8. B = {μ}_{0} ( H + M )$$

This inverse model is used to derive estimates of M (bulk magnetization) given periodic measurements of B (the induced core magnetic field). In normal operation in the sensor system 10a or 10b, the inverse model is used because we are measuring B with the transducers 12 and/or 26 which convert the magnetic field density in the core 20 to an electrical signal. Once M is calculated, H (the impressed magnetic field from the main conductor which is proportional to current in the main conductor) is calculated from B and M, and this value is proportional to the current being sensed.

The forward model is used for model training purposes, since in this case we know H (from the known applied test currents) and are trying to get the model to predict B (which is proportional to the HED transducer output). The forward model is as follows:

$$1. \frac{d M}{d H} = \frac{( 1 - c ) \frac{d {M}_{irr}}{d {H}_{e}} + c \frac{d {M}_{an}}{d {H}_{e}}}{1 - α c \frac{d {M}_{an}}{d {H}_{e}} - α ( 1 - c ) \frac{d {M}_{irr}}{d {H}_{e}}}$$

$$2. {M}_{an} = {M}_{s} [ coth \frac{{H}_{e}}{a} - \frac{a}{{H}_{e}} ]$$

$$3. \frac{d {M}_{an}}{d {H}_{e}} = \frac{{M}_{s}}{a} [ 1 - {coth}^{2} \frac{{H}_{e}}{a} - {( \frac{a}{{H}_{e}} )}^{2} ]$$

$$4. {H}_{e} = H + α M$$

$$5. \frac{d {M}_{irr}}{d {H}_{e}} = \frac{{M}_{an} - {M}_{irr}}{k δ}$$

$$where$$

$$δ = sign ( \frac{d H}{d t} )$$

$$6. B = {μ}_{0} ( H + M )$$

Once the forward model is properly predicting B given a known H, we apply the identified optimal model parameters [Mₛ,a,α,k,c] to the inverse model for use in the sensor.

A Model optimization method can derive the optimal model parameters, a particle swarm optimization (PSO) algorithm is used. The technique is iteratively uses evolving estimations of the five model parameters to eventually converge on a set that accurately predicts M and B given the experimentally measured H values and HED readings. Remember H is exactly proportional to the current we want the sensor to measure while B is being sensed by the transducers 12 and/or 26.

To implement this technique in the actual sensor system 10a or 10b, one must use simplified numerical methods so as not to over burden the limited computational capacity of the microcontroller 14. The following is a step by step procedure that the sensor processor will execute each time sample period to update its current output signal:
1. Calculate the step change in B. ΔB(n)=Bₙ−Bₙ,
2. Calculate the effective H from: Hₑ(n)=Hₙ₋₁−αMₙ₋₁,
3. Find the reversible core magnetism by:

$$a . {M}_{an} ( n ) = {M}_{s} \frac{{H}_{e}}{3 a} if \frac{{H}_{e}}{a} < 0.01$$

$$b . else , {M}_{an} ( n ) = {M}_{s} [ coth \frac{{H}_{e}}{a} - \frac{a}{{H}_{e}} ]$$

where coth(x) is approximated in a lookup table.
4. Find the irreversible portion of M by:
   a.

$${M}_{irr} ( n ) = \frac{M ( n - 1 ) - {cM}_{an} ( n )}{1 - c}$$

5. Calculate the following derivative:

$$a . \frac{d {M}_{an}}{d {H}_{e}} ( n ) = {M}_{s} \frac{1}{3 a} if \frac{{H}_{e}}{a} < 0.01$$

$$b . else , \frac{d {M}_{an}}{d {H}_{e}} ( n ) = \frac{{M}_{s}}{a} [ 1 - {coth}^{2} \frac{{H}_{e}}{a} - {( \frac{a}{{H}_{e}} )}^{2} ]$$

6. Find the following derivative:

$$a . \frac{d {M}_{irr}}{d {B}_{e}} ( n ) = \frac{{M}_{an} ( n ) - {M}_{irr} ( n )}{{μ}_{0} k δ}$$

$$where$$

$$δ = sign ( \frac{d H}{d t} )$$

7. Next, insert these values into:

$$a . \frac{d M}{d B} = \frac{( 1 - c ) \frac{d {M}_{irr}}{d {B}_{e}} + \frac{c}{{μ}_{0}} \frac{d {M}_{an}}{d {H}_{e}}}{1 + {μ}_{0} ( 1 - c ) ( 1 - α ) \frac{d {M}_{irr}}{d {B}_{e}} + c ( 1 - α ) \frac{d {M}_{an}}{d {H}_{e}}}$$

$$b . and integrate using a simple Euler method \text{:}$$

$$M ( n ) = M ( n - 1 ) + \frac{d M}{d B} Δ B$$

8. Finally, extract H with H(n)=B(n)/μ₀−M(n), and multiply H by a constant also found during training to yield the final sensor output value.

Afterwards, in step 40, the linearized transducer value is converted to a signal outputted by the microcontroller output. The output signal may take any one of variety of different standard forms. For example, the output signal may be a single edge nibble transmission signal (SENT), a pulse with modulated signal (PWM), or may be an analog signal, or can be any signal capable of transmitting data.

In other embodiments, dedicated hardware implementations, such as application specific integrated circuits, programmable logic arrays and other hardware devices, can be constructed to implement one or more of the methods described herein. Applications that may include the apparatus and systems of various embodiments can broadly include a variety of electronic and computer systems. One or more embodiments described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionality as described herein.

Further, the methods described herein may be embodied in a computer-readable medium. The term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

As a person skilled in the art will readily appreciate, the above description is meant as an illustration of implementation of the principles this invention. This description is not intended to limit the scope or application of this invention in that the invention is susceptible to modification, variation and change, without departing from the spirit of this invention, as defined in the following claims.

1. A sensor system comprising:
a first transducer having a first transducer output, the first transducer being configured to measure a parameter and output a first transducer signal to the first transducer output, the first transducer signal based on the parameter measured by the first transducer, the first transducer signal having a non-linear range; and
a microcontroller in communication with the first transducer output and having a microcontroller output, the microcontroller being configured to output a signal based on the first transducer signal, wherein the signal has a linear range.

2. The sensor system of claim 1, wherein the first transducer is a Hall effect device and wherein the parameter to be measured is a magnetic field.

3. The sensor system of claim 1, wherein the microcontroller further comprises an analog to digital converter, the analog to digital converter being configured to convert the first transducer signal to a digital transducer value.

4. The sensor system of claim 3, wherein the microcontroller is further configured to filter the digital transducer value using a filter.

5. The sensor system of claim 4, wherein the filter is at least one of a median value filter and an infinite impulse response low-pass filter.

6. The sensor system of claim 4, wherein the microcontroller is further configured to linearize the digital transducer value to create a linearized transducer value.

7. The sensor system of claim 6, wherein the microcontroller is configured to linearize the digital transducer value by utilizing a lookup table, the lookup table containing conversion value for converting the digital transducer value to the linearized transducer value.

8. The sensor system of claim 7, wherein the microcontroller is further configured to convert the linearized transducer value to the signal outputted to the microcontroller output.

9. The sensor system of claim 8, wherein the signal outputted by the microcontroller output is at least one of a single edge nibble transmission signal, a pulse width modulated signal, and an analog signal.

10. The sensor system of claim 8, wherein the microcontroller is configured to apply a hysteresis algorithm to the digital transducer value for reminance cancellation.

11. The sensor system of claim 10, wherein the hysteresis algorithm utilizes the Jiles-Atherton model.

12. The sensor system of claim 1, further comprising:
a second transducer having a second transducer output, the second transducer being configured to measure the parameter and output a second transducer signal to the second transducer output, the second transducer signal based on the parameter measured by the second transducer, the second transducer signal having a non-linear range; and
the microcontroller being in communication with the second transducer output, the microcontroller being configured to output a signal based on the first and second transducer signals, wherein the signal has a linear range.

13. A method for interpreting a signal from a transducer, the method comprising:
receiving a first transducer signal from a first transducer, the first transducer signal based on the parameter measured by the first transducer, the first transducer signal having a non-linear range; and
outputting an output signal based on the first transducer signal, wherein the output signal has a linear range.

14. The method of claim 13, wherein the first transducer is a Hall effect device and wherein the parameter to be measured is a magnetic field.

15. The method of claim 13, further comprising the step of converting the first transducer signal to a digital transducer value.

16. The method of claim 15, further comprising the step of filtering the digital transducer value using a filter.

17. The method of claim 16, wherein the filter is at least one of a median value filter and an infinite impulse response low-pass filter.

18. The method of claim 16, further comprising the step of linearizing the digital transducer value to create a linearized transducer value.

19. The method of claim 18, wherein the step of linearizing utilizes a lookup table, the lookup table containing conversion value for converting the digital transducer value to the linearized transducer value.

20. The method of claim 19, further comprising the step of converting the linearized transducer value to the signal outputted to the microcontroller output.

21. The method of claim 20, wherein the output signal is at least one of a single edge nibble transmission signal, a pulse width modulated signal, and an analog signal.

22. The method of claim 20, wherein the microcontroller is configured to apply a hysteresis algorithm to the digital transducer value for reminance cancellation.

23. The method of claim 22, wherein the hysteresis algorithm utilizes the Jiles-Atherton model.

24. The method of claim 13, further comprising:
receiving a second transducer having a second transducer output, the second transducer signal based on the parameter measured by the second transducer, the second transducer signal having a non-linear range; and
outputting the output signal based on the first and second transducer signals, wherein the output signal has a linear range.
